(19) United States
(12) Patent Application Publication
(10) Pub. No.: US 2003/0117780 A1
(43) Pub. Date: Jun. 26, 2003

(54) Apparatus having contacts made from carbon tracks and method of producing them

(76) Inventors: Hubert Farizon, Le Mans (FR); Jean-Michel Grigne, Montfort-le-Gesnois (FR)

Correspondence Address: PHILIPS ELECTRONICS NORTH AMERICAN CORP, 580 WHITE PLAINS RD, TARRYTOWN, NY, 10591, US

(21) Appl. No.: 10/201,674

(22) Filed: Jul. 23, 2002

(30) Foreign Application Priority Data
Jul. 26, 2001 (FR) 0110010

(51) Int. Cl. H05K 1/14

(52) U.S. Cl. 361/736

(57) ABSTRACT

This apparatus has a printed circuit board 10 and contacts made from carbon tracks. These carbon tracks (52, 44) are disposed on the printed circuit board (10) by means of an insulating layer (54, 42) plated on the printed circuit board.

Application: Production of a keypad for a mobile telephone.

### DESCRIPTION

The invention relates to an apparatus containing a printed circuit board and contacts made from carbon tracks.

The invention also relates to a method of manufacturing such contacts.

The invention finds important applications in particular with regard to the production of keypads on small-sized apparatus.

Thus, for example, to limit the size of mobile telephone apparatus, the contacts of the buttons on the keypad are disposed on the printed circuit board which contains practically all the components of the apparatus. These printed circuit boards are composed of a plurality of layers, typically 2 to 4 layers. These layers have many holes passing right through them, placed very close to each other.

The problem which is then posed is due to the contacts on the keypad in the form of carbon tracks. The presence of the holes interferes with the path of the tracks, and the carbon deposit may infiltrate in said holes.

The present invention proposes an apparatus of the type mentioned in the preamble which allows the use of carbon tracks while keeping a low cost price.

For this purpose, such an apparatus is characterized in that the carbon tracks are disposed on the printed circuit board by means of an insulating layer plated on the printed circuit board.

A method of manufacturing such a keypad includes the following steps:

plugging, at least partially, at least said holes,

depositing an insulating layer on said printed circuit board,

depositing carbon tracks for said keypad.

The invention will be further described with reference to examples of embodiment shown in the drawings to which, however, the invention is not restricted. In the drawings:

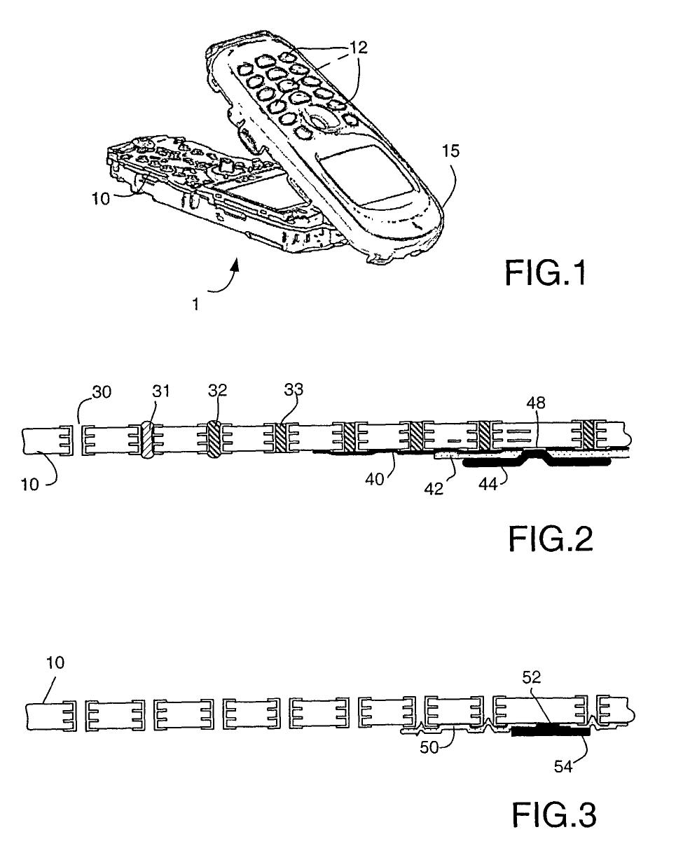

FIG. 1 shows an apparatus according to the invention.

FIG. 2 shows a first embodiment of the invention.

FIG. 3 shows a second embodiment of the invention.

In FIG. 1, the apparatus bears the reference 1. This apparatus, in the context of the example described, is a mobile telephone for a cellular network. This apparatus is shown in an exploded view which reveals the printed circuit board 10 which contains almost all the electronic components of this apparatus. This apparatus has a keypad whose keys 12 are visible on the front face 15 of the apparatus.

The printed circuit board 10 has a multitude of holes or passages (called vias in the technical English literature). FIG. 2 shows how these holes are treated for applying the invention. In FIG. 2, the reference 30 shows a through hole as it is initially.

According to the invention, this passage is first of all plugged with any plugging material. This is shown by the reference 31. This padding substance is then hardened in an oven for example to make it easier to machine. This is shown by the reference 32. The padding is then leveled, as shown by the reference 33. On the holes on the keypad side a layer of resin 40 (resist) is placed to level the surface. On this resin 40 there is placed a layer of insulating material 42 on which the layer of carbon 44, intended for the keypad, is finally placed. The contact between this carbon track is provided by a gold-plated area 48 of the printed circuit.

Another embodiment is shown in FIG. 3. According to this embodiment, photosensitive sheets 50 are used to make the printed circuit board 10 flatter. This sheet is a VACREL sheet manufactured by Dupont. This product polymerizes under ultraviolet radiation and hardens sufficiently for the implementation of the invention. In addition, it has been possible to form the contact area 52 on the card 10. This sheet permits the attachment of the carbon tracks 54 for the keypad keys 12.

Although the invention has been described in the context of a keypad, it goes without saying that it covers all cases where it is a question of depositing a layer of carbon on a sheet with protuberances.

1. An apparatus containing a printed circuit board and contacts made from carbon tracks, characterized in that the carbon tracks are disposed on the printed circuit board by means of an insulating layer plated on the printed circuit board.

2. An apparatus as claimed in claim 1, characterized in that an intermediate leveling layer is coated between the printed circuit board and said insulating layer.

3. A method of producing carbon track contacts on a printed circuit board having a multitude of passages, characterized in that it includes the following steps:
at least partially plugging at least one of said passages,
depositing a layer isolating in itself on said printed circuit board,
depositing carbon tracks for said keypad.

4. A method as claimed in claim 3, characterized in that an additional step is provided for inserting an intermediate leveling layer against the printed circuit board.

5. An apparatus as claimed in one of claims 1 or 2, characterized in that it has a keypad whose contacts are produced by means of carbon tracks.
